(19) United States
(12) Patent Application Publication
(10) Pub. No.: US 2025/0065733 A1
(43) Pub. Date: Feb. 27, 2025

(54) INVERTER ARRANGEMENT FOR A VEHICLE, AND VEHICLE HAVING THE INVERTER ARRANGEMENT

(71) Applicant: ZF Friedrichshafen AG, Friedrichshafen (DE)

(72) Inventors: Ake Ewald, Bayreuth (DE); Michael Sperber, Bayreuth (DE)

(73) Assignee: ZF Friedrichshafen AG, Friedrichshafen (DE)

(21) Appl. No.: 18/688,514

(22) PCT Filed: Sep. 2, 2022
(86) PCT No.: PCT/EP2022/074436

§ 371 Date: Mar. 1, 2024

(30) Foreign Application Priority Data
Sep. 3, 2021 (DE) 10 2021 209 724.3

(51) Int. Cl. B60L 50/51

(52) U.S. Cl. CPC B60L 50/51; B60L 2210/42; B60L 2240/52

(57) ABSTRACT

An inverter assembly for a vehicle has numerous switch modules, wherein each switch module has at least one switch, wherein some of the switches are high-side switches and some of the switches are low-side switches, with an intermediate circuit capacitor and at least one phase output, wherein the switches are connected at the input side to the intermediate circuit capacitor, and at the output side to the at least one phase output, wherein the switch modules each have at least one main surface, wherein the main surfaces of the module are the sides of the switch modules with the greatest surface area, wherein numerous switch modules are placed upright in a row, with their main surfaces parallel to one another, in the inverter assembly.

The invention relates to an inverter assembly for a vehicle that has the features in the preamble of claim 1. The invention also relates to a vehicle that has this inverter assembly.

Inverters are needed for the drives in electric vehicles and hybrid vehicles, with which an alternating current is generated from the direct current provided by a battery or generator, in order to power an electric motor in a vehicle. The core components of the inverter are switches with which electrical connections are established or disconnected, depending on the phasing. In particular, semiconductor switches are used that can withstand the switching frequency as well as the switching current, but become hot in operation and therefore must be placed appropriately for their use.

In the prior art, the switches are placed adjacent to one another on a surface, such that they can be actively cooled from below and passively cooled from above through convection and/or thermal radiation.

The object of the present invention is to create an inverter assembly for a vehicle that is particularly compact. This problem is solved by an inverter assembly that has the features of claim 1 and a vehicle that has the features of claim 15. Preferred embodiments of the invention can be derived from the dependent claims and the description in conjunction with the drawings.

An inverter assembly is disclosed by the invention that can be used in and/or is designed for use in a vehicle. The vehicle is an electric vehicle or hybrid vehicle. The vehicle has at least one traction motor for powering the vehicle. The traction motor is an electric motor.

The purpose of the inverter assembly is to generate alternating current, in particular an alternating current supply, from direct current.

The invention contains numerous switch modules, each of which contains at least one switch. Consequently, there can be exactly one, or two or more, switches in each switch module.

Some of the switches are high-side switches, and the other switches are low-side switches.

The inverter assembly has one intermediate circuit capacitor and at least one phase output. The inverter assembly preferably has exactly three phase outputs, such that the AC supply can be operated with three phases. The switches are connected at the input side to the intermediate circuit capacitor, and at the output side to the at least one phase output. In particular, the high-side switches are connected to a DC (+) output in the intermediate circuit capacitor, and the low-side switches are connected to a DC (−) output in the intermediate circuit capacitor.

A preferably three-phase alternating current supply can be generated with this design and the appropriate activation of the switch modules and/or switches.

The switch modules each have at least one main surface. The main surface of the module is that with the greatest surface area. The switch modules can also have two opposing main surfaces. By way of example, one main surface can be the front, and the other main surface can be the back of the switch module. Lateral surfaces encompass the switch module, which are smaller, or preferably even significantly smaller than the main surfaces.

It is proposed in the framework of the invention that numerous switch modules be placed in a stack and/or row, upright, in the inverter assembly, with their main surfaces parallel to one another. This results in parallel switch modules, standing on edge in a row in the inverter assembly. The switch modules are particularly preferably congruent, or at least overlapping, when seen from a perspective perpendicular to the main surfaces of the module. In particular, the switch modules are stacked, with a spacing between them.

One consideration of the invention is that in the prior art, the switches are placed adjacent to one another on a surface, such that they can be actively cooled from below and passively cooled through convection and/or thermal radiation from above. This has the disadvantage that it requires a relatively large area, and problems may arise with regard to the lengths of the connecting wires for the high-side switches and low-side switches, if they are behind one another. The inverter assembly according to the invention makes use of the third dimension, thus reducing the necessary space for the switch modules in the inverter assembly.

In a preferred version of the invention, the parallel main surfaces of the switch modules are parallel to a plane defined by the Y and Z-axes, and or parallel to one another. The main surface of the intermediate circuit capacitor is parallel to an X-Y plane. The main surface of the capacitor is the surface with the greatest surface area. The main surfaces of the modules, or their planes, are therefore perpendicular to the main surface of the intermediate circuit capacitor.

With this arrangement, the switch modules can be placed parallel to one another on a lateral surface of the intermediate circuit capacitor in a space-saving manner.

From a functional perspective, each phase output preferably has at least one dedicated high-side switch and at least one dedicated low-side switch. Consequently, a complete phase can be activated and/or generated with each phase output.

In a preferred version of the invention, each phase output has two or more dedicated high-side switches and/or two or more low-side switches.

In a first variation of the invention, all of the high-side switches for a single phase output are adjacent to one another and/or all low-side switches for the phase output are adjacent to one another. This results in a group of high-side switches and a group of low side switches that are adjacent to one another. This design has the advantage of being able to create a simple connection to the intermediate circuit capacitor.

In alternative design, the high-side switches and low-side switches are symmetrically arranged over a central plane. The central plane extends in the Y-Z plane and divides the switches for a phase output symmetrically. In particular, at least one high-side switch is placed between two low-side switches. There can also be two or more high-side switches between two low-side switches. There can also be at least one low-side switch between two high-side switches for the phase output. There can also be two or more low-side switches between two high-side switches for the phase output. This symmetrical arrangement has the advantage of a minimum of commutating cells, reducing the necessary compensating current in the intermediate circuit of the intermediate circuit capacitor.

In one version of the invention, at least one, some, or all of the switch modules have at least one high-side switch and at least one low-side switch. These switch modules form a half bridge. In this design, a phase output can be supplied for all of the phases by a single switch module. There can also be two or more of these switch modules for each phase output.

The switch module preferably has a box-shaped body. The front and back surfaces of the body are formed by the main surfaces of the module. The connections for the switch module protrude from the body. In particular, the switch module can have a housing, which forms, or is part of, the body.

Preferably, at least one of the switch modules has at least one power semiconductor for a switch. This power semiconductor is parallel to the main surface of the module and/or extends in the Y-Z plane. This expands the parallel arrangement of the switch modules with a parallel arrangement of switches, in particular the power semiconductors. The power semiconductor particularly preferably does not have a housing. The material for the power semiconductor can be, e.g. Si, SiC, GaN, etc. The semiconductors can be, e.g., IGBTs, MOSFETs, cascodes, etc.

At least one of the switch modules particularly preferably has a ceramic/copper printed circuit board, which is parallel to the main surface of the module and/or parallel to the Y-Z plane. The ceramic/copper printed circuit board is preferably a DCB (Direct Copper Bonding) substrate or an IMS (Insulated Metal Substrate). The ceramic/copper printed circuit board is particularly advantageous for the removal and/or discharge of thermal energy. The switch or switches, in particular in the form of power semiconductors, are preferably placed directly on the ceramic/copper printed circuit board, in particular soldered thereto.

At least one of the switch modules, in particular one of the switch modules with the ceramic/copper printed circuit board, has a cooling element, which is parallel to the main surface of the module and/or parallel to the Y-Z plane. The cooling element is preferably an active cooling element, specifically a liquid cooling element. The cooling element is in contact with the ceramic/copper printed circuit board. By way of example, the cooling element covers the entire surface of the ceramic/copper printed circuit board. In particular, the cooling element is selectively and/or exclusively dedicated to the switch module.

If the switch module contains two switches, one of which is a high-side switch and the other a low-side switch, the switch module preferably contains two ceramic/copper printed circuit boards populated with the switches, with the cooling element between the switches and/or the ceramic/copper printed circuit board, in order to actively cool the switches. This results in a switch module with a sandwich structure.

The cooling element preferably has a cooling connection that extends downward along the Z-axis. This cooling connection is on one of the lateral surfaces of the switch module.

In a preferred version of the invention, at least one of the switch modules has a control and/or measurement connection, which extends upward along the Z-axis. In particular, this control and/or measurement connection is opposite the cooling connection. Consequently, the control and/or measurement connection is on another lateral surface of the switch module, in particular on the opposing side.

All of the control and/or measurement connections on the switch modules in the inverter assembly preferably extend in the same direction, such that contact can be made to the entire switch module from one side.

The inverter assembly particularly preferably has a control and/or measurement printed circuit board, which is placed on the numerous switch modules, such that the control and/or measurement connections that extend upward can be received in the control and/or measurement printed circuit board. This design simplifies the contact to the switch module, and results in a space-saving structure.

At least one of the switch modules preferably has an input connection for the intermediate circuit capacitor, and one output connection for the phase output, which are on opposite sides of switch module, and/or extend in both directions along the Y-axis.

Two opposing sides of the switch module are used for the input connection and output connection, and two other opposing sides are used for the cooling connection and the control and/or measurement connection. Each lateral surface of the switch module therefore has a different function. Because the lateral surfaces are used for the connections, they have no effect on the thickness of the switch module, and it can be placed in a space-saving manner in the inverter assembly.

In a preferred version of the invention, the input connection has an input contact surface and the output connection has an output contact surface. The input contact surface and output contact surface extend in the X-Y plane, and/or perpendicular to the main surface of the module. On output for the intermediate circuit capacitor has a complementary input contact surface, which extends in the same plane as the input contact surface. The phase output has a complementary output contact surface, which extends in the same plane as the output contact surface. This allows the switch module to be inserted downward along the Z-axis against the complementary contact surfaces, to obtain electrical contact. Contact to the cooling connection can also be obtained along the Z-axis by pressing it down against the complementary cooling connection in the inverter assembly, such that the cooling element is connected to a fluid source.

In a preferred version of the invention, the inverter assembly has one or more fasteners with which the switch module is held down. In particular, the switch module is pushed downward with the fasteners, such that the input contact surfaces and output contact surfaces, and/or the cooling connection are inserted in the correct manner. The fastener is preferably a strip that extends along the X-axis.

A vehicle that has the inverter assembly described above or according to any of the preceding claims is also part of the subject matter of the invention. The vehicle has at least one traction motor, and the inverter assembly is designed to supply alternating current to the traction motor.

The following description and drawings disclose preferred exemplary embodiments of the invention. Therein:

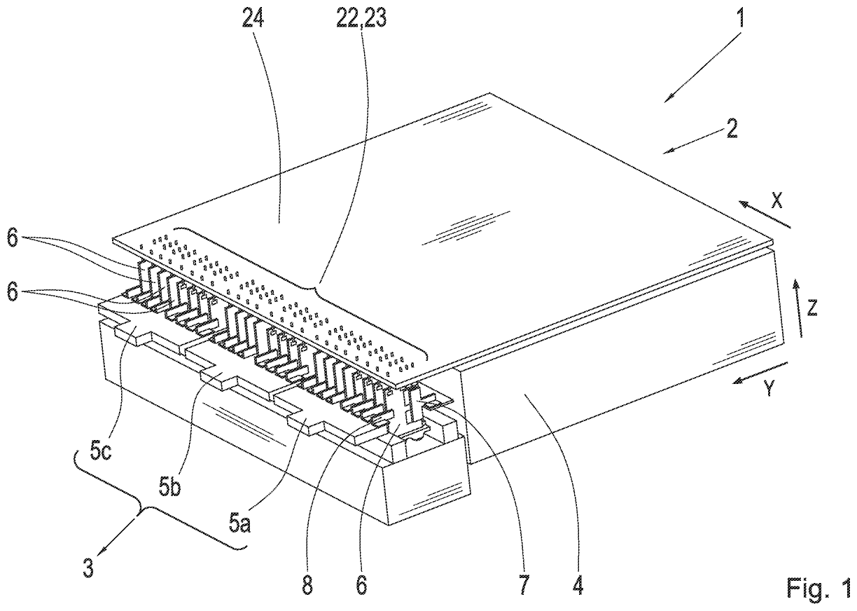

FIG. 1 shows a schematic, three dimensional illustration of an inverter assembly forming an exemplary embodiment of the invention;

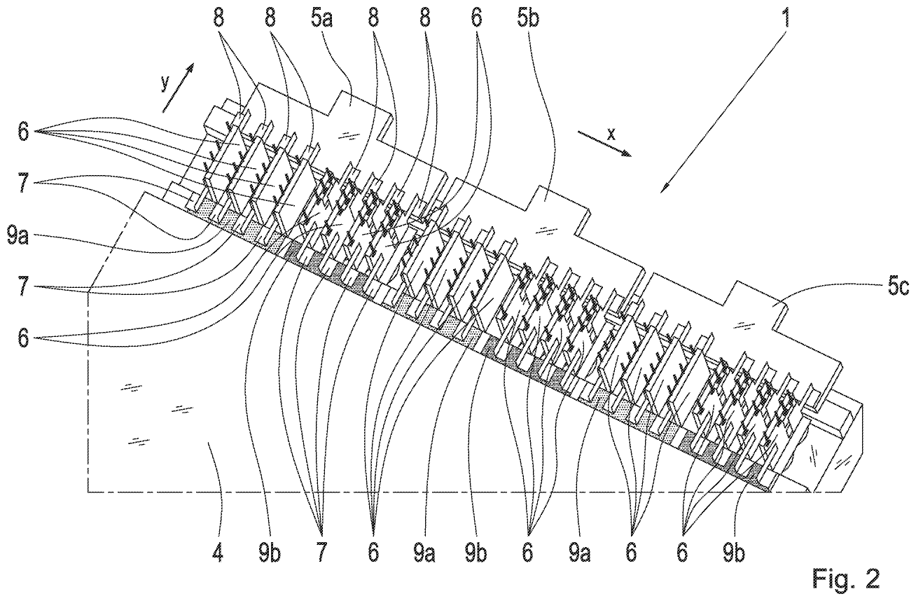

FIG. 2 shows a detail of the inverter assembly in FIG. 1;

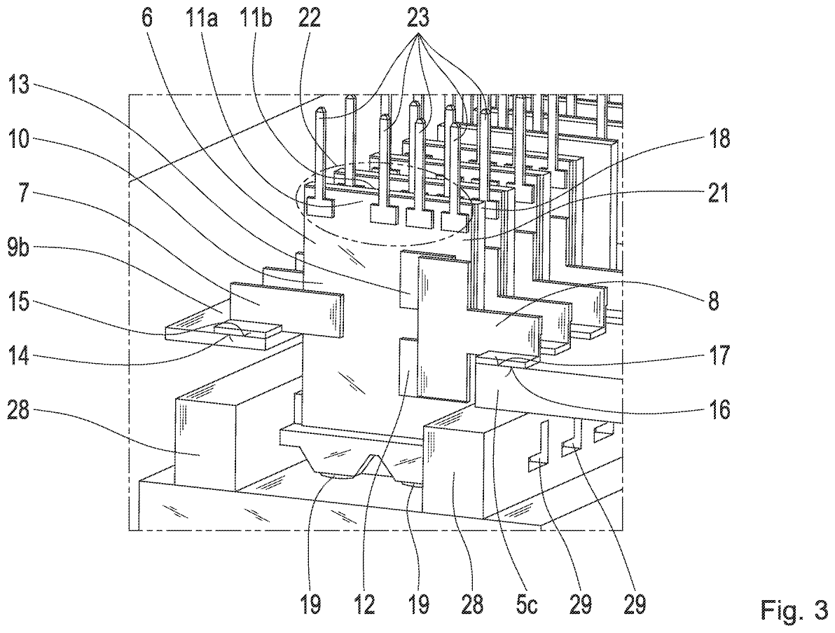

FIG. 3 shows another detail of the inverter assembly shown in the preceding figures;

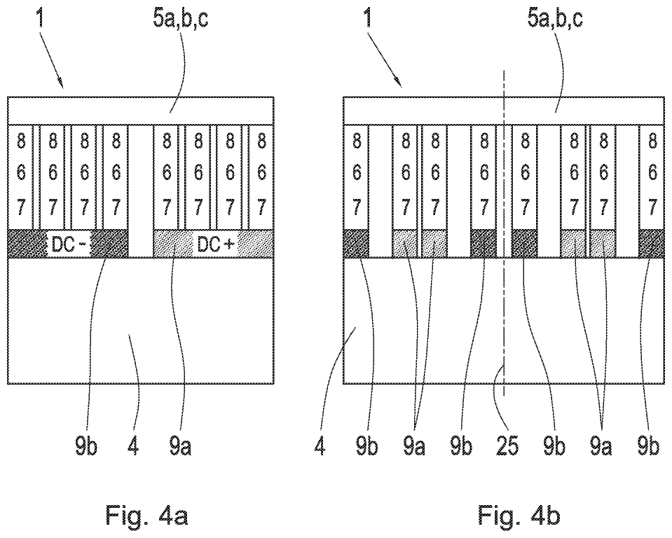

FIGS. 4a, b show a schematic view from above of a connecting region on the inverter assembly in the preceding figures, with different arrangements of the switch modules;

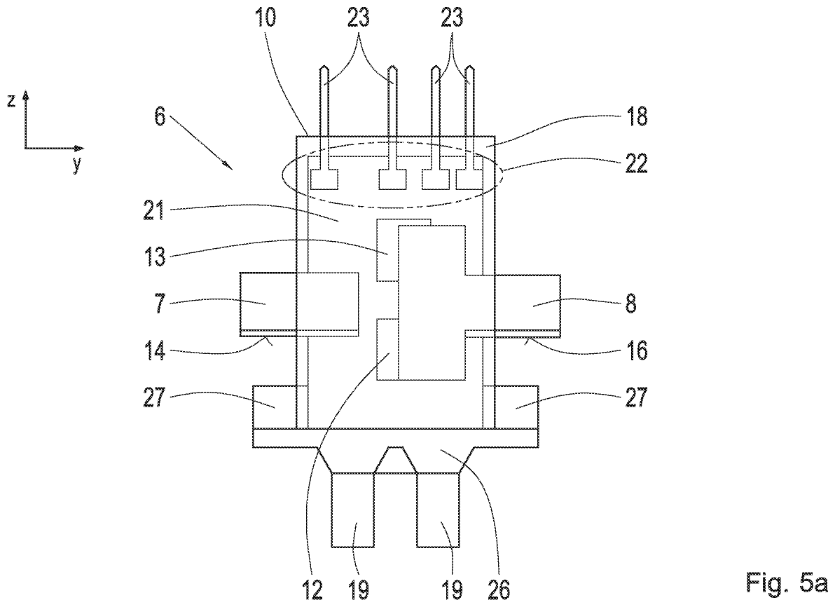

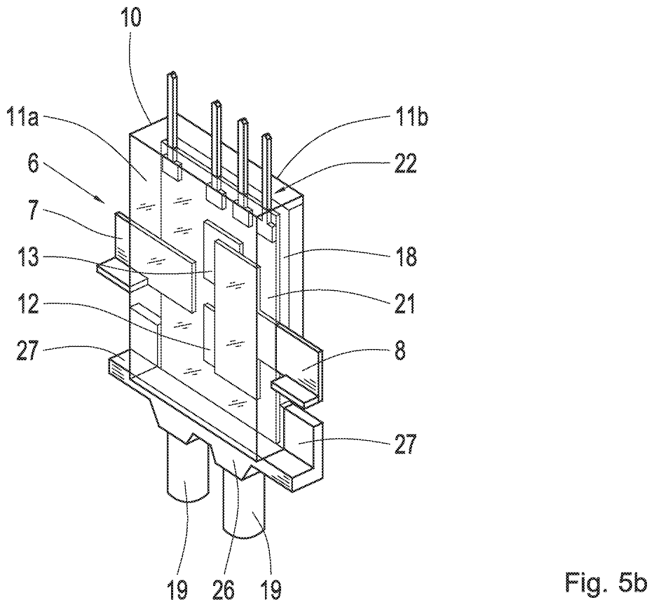

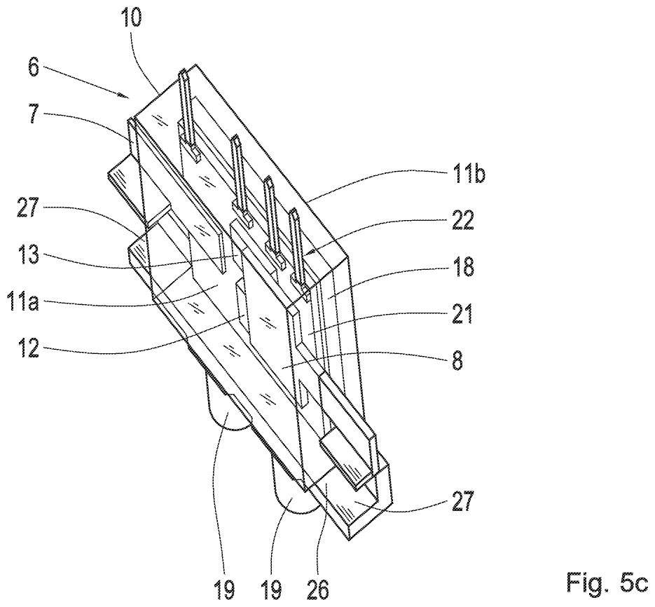

FIGS. 5a, b, c show three dimensional illustrations of a switch module for the inverter assembly from different perspectives, forming an exemplary embodiment of the invention;

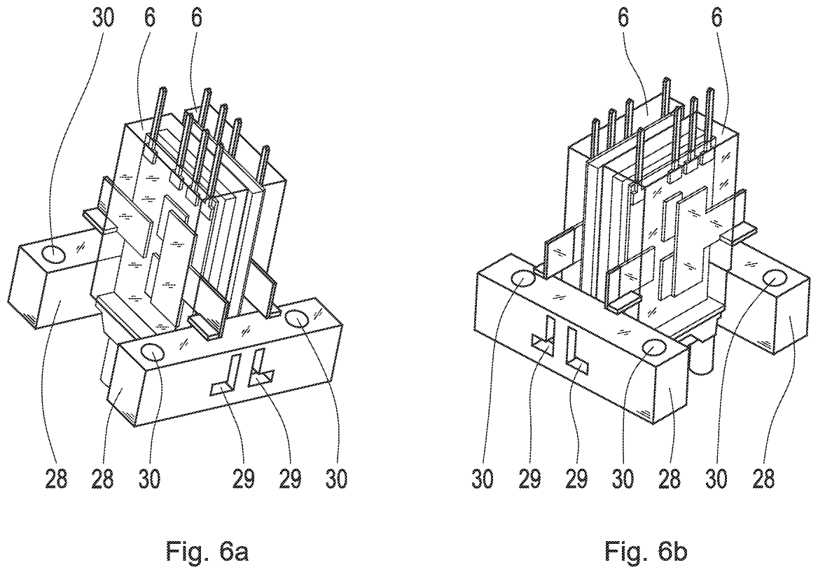

FIGS. 6a, b show three dimensional illustrations of the switch module from different perspectives when it is installed;

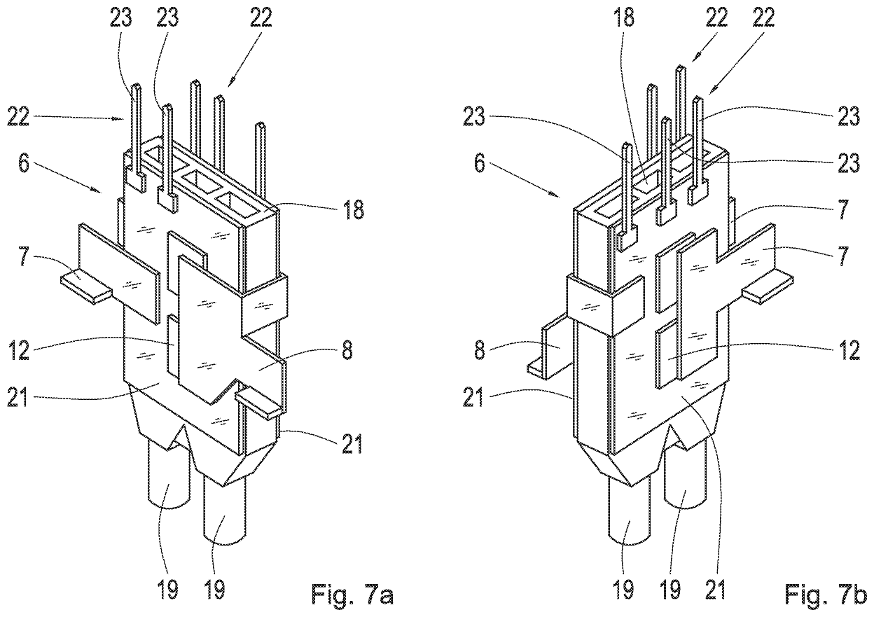

FIGS. 7a, b show three dimensional illustration of another exemplary embodiment of the inventive switch module for the inverter assembly in the preceding figures from different perspectives; and

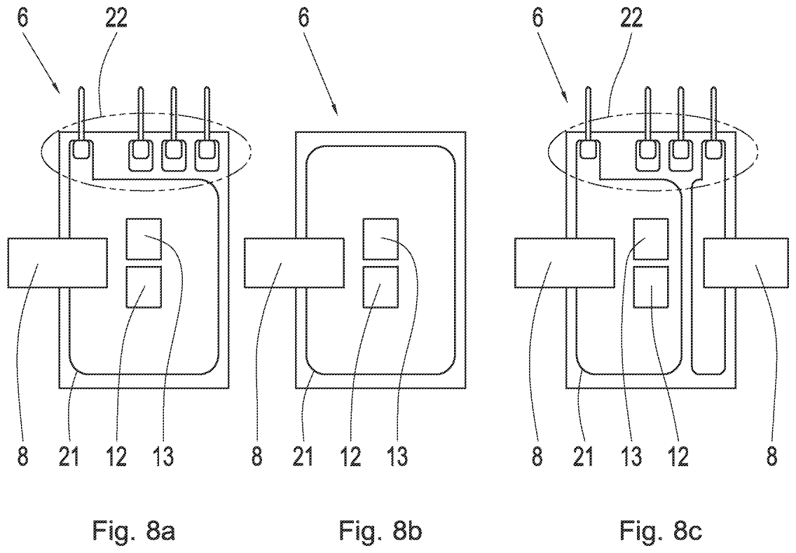

FIGS. 8a, b, c show different variations of a ceramic/copper printed circuit board from above for the switch modules in the preceding figures.

Identical or corresponding components or regions have the same or corresponding reference symbols in the figures. The description relates in the same manner to all of the figures.

FIG. 1 shows an inverter assembly 1 in a schematic, three dimensional illustration, forming an exemplary embodiment of the invention. The inverter assembly 1 can also be referred to as a current inverter. The inverter assembly 1 generates alternating current from a direct current supply 2 obtained from a battery or a fuel cell, for example. It is used in particular to provide alternating current to a vehicle, specifically for an electric motor in the form of a traction motor for the vehicle.

The inverter assembly 1 has an intermediate circuit capacitor 4, which is connected at the input side to the battery or fuel cell (not shown). The inverter assembly 1 also has three phase outputs 5a, b, c, with which the three phases of the alternating current are obtained. The phase outputs 5a, b, c are conductive T-shaped elements, the upright leg of which forms a connection to the electric motor, and the crossbar of which forms a contact for the intermediate circuit capacitor.

There are numerous parallel switch modules 6 that are electrically interconnected between the intermediate circuit capacitor 4 and the phase outputs 5 a, b, c. The switch modules 6 each have input connections 7 that come in contact with the intermediate circuit capacitor 4, and output contacts 8, connected in parallel to a phase output 5a, b, c, in particular at the upright leg.

To simplify the description, the intermediate circuit capacitor 4 forms a plane defined by the X and Y-axes, and the vertical direction in the inverter assembly 1 is defined by the Z-axis.

FIG. 2 shows a schematic three dimensional illustration of the connecting region on the inverter assembly 1 from above, where the switch module 6 is located. In this illustration, the phase outputs 5a, b, c on the output side of the switch modules 6 are shown, and the high-side outputs 9a and low-side outputs 9b on the input side for the intermediate circuit capacitor 4 are shown. A DC (+) voltage from the intermediate circuit capacitor 4 is at the high-side outputs 9a, and a DC (−) voltage from the intermediate circuit capacitor 4 is at the low-side outputs 9b. The input connections 7 are connected to the high-side outputs 9a or the low-side outputs 9b. The output connections 8 are connected to the phase outputs 5a, b, c. Each phase output 5a, b, c, has a dedicated group of switch modules 6 connected to a high-side output 9a, and a group of switch modules 6 connected to a low-side output 9b.

FIG. 3 shows a detail of the region of the inverter assembly 1 containing the switch modules 6 in a schematic, three dimensional illustration. This shows that each of the switch modules 6 has a box-shaped, or rectangular, body 10. The switch modules 6 each have a main surface 10a, b that forms the front or back surface of the body 9, or switch module 6. Lateral surfaces encompass the switch module 6, which have significantly smaller surface area than the main surfaces 11a, b.

The main surfaces 11a, b of the module are parallel to the Y-Z plane. In particular, the switch modules 6 are placed on edge in the inverter assembly 1. The switch modules 6 in this exemplary embodiment are stood on edge in a row, such that the main surfaces 11a, b of the switch modules 6 are parallel to one another. The switch modules 6 form a stack. When seen along the X-axis, they are congruent to other. There is a spacing between the switch modules, such that they do not inadvertently come in contact with one another, and can be more effectively cooled.

There are switches 11 and optional, supplementary diodes 12 on the switch modules. These switches 12 and diodes 13 are parallel to the main surfaces 11a, b of the modules, and/or the Y-Z plane. The switches 12 are power semiconductors. The switches 12 and diodes 13 do not have housings. By way of example, the switches 12 are IBGT chips, and the absence of housings minimizes any electrical resistances or thermal resistances, thus increasing the energy efficiency and thermal output.

The input connections 7 each have an input contact surface 14 that is parallel to the X-Y plane and comes in contact with a complementary input contact surface 15 on the high-side output 9a or low-side output 9b. The output connections 8 each have output contact surfaces 16 that are in the X-Y plane and come in contact with the complementary output contact surfaces 17 on the phase outputs 5a, b, c.

Each of the switch modules 6 has a cooling element 18 that is parallel to the main surfaces 11a, b of the modules and/or the Y-Z plane. The cooling element 18 has cooling connections 18 that extend downward and can be inserted into their complementary cooling connections 20 from above.

When the switch module is inserted downward, both the electrical contacts and the connection to the cooling circuit are obtained.

Each switch module 6 has a ceramic/copper printed circuit board 21 that is parallel to the main surfaces 10a, b of the main module 10a, b, and or forms one of these surfaces. The ceramic/copper printed circuit board 21 is formed in particular by a DCB (Direct Copper Bonding) substrate. In particular, switches 12 and/or diodes 13 are placed directly on the DCB substrate, which has the same expansion coefficient as silicon.

In particular, the cooling element 18 is in contact with the ceramic/copper printed circuit board 20. The ceramic/copper printed circuit board 20 has the same surface area as the cooling element 18 in this exemplary embodiment. In particular, the cooling element covers the entire surface of the ceramic/copper printed circuit board 21.

The switch modules 6 each have a control and/or measurement connection 21 that is formed by numerous pins 23 that extend upward.

Consequently, a control and/or measurement printed circuit board 23 can be connected to the switch module 6 by pressing it downward onto the switch module 6.

In summary, the switch modules 6 have input connections 7 and output connections 8 on opposite sides along the Y-axis, and/or cooling connections 19 and control and/or measurement connections on two other opposing sides along the Z-axis.

The inverter assembly 1 exploits the third dimension in order to reduce the necessary installation space for the power semiconductors therein, as can be seen in the drawings.

The inverter assembly 1 is distinctive in that
numerous switch modules 6 can be connected to a single electrical phase,
one or more switch modules 6 form a high-side and low-side switch within an electrical phase, in which the switch modules 6 in a switch can be connected in parallel,
numerous phases, three in the drawings, are obtained for an electric drive,
a one-piece or multi-part intermediate circuit capacitor 4 supplies the switches 12, in particular power semiconductors, with direct current,
there is an intake and outlet for the coolant, such that the switch modules 6 can be cooled in series or in parallel,
there is a printed circuit board in the form of a control and/or measurement printed circuit board 24, with which the switch modules 6 can be controlled, and which can contain the necessary protective circuitry for the semiconductors. The switch modules can be connected to the measurement and control connections with the printed circuit board. Furthermore, the printed circuit board allows numerous dies to be connected in parallel on each topological switch.

Four switch modules 6 in each topological switch are connected to one another in the inverter assembly 1 shown in FIG. 4a. Each switch module 6 contains the power semiconductors forming the switches 12. Each topological switch can also contain some other number of switch modules 6 connected in parallel. The topological switches are connected to a high side and a low side, which can form the alternating current of a phase.

The inverter assembly 1 has three electrical phases, which can be used to power an electric motor. The power semiconductors are connected at one side to the intermediate circuit capacitor 4 by DC+ and DC− connections.

On the lower surface, the cooling elements 18 are inserted in a coolant distributor. The modules are held in place by fasteners 28 in the form of clamps, which are connected to the distributor or the housing. On the upper surface, the measurement and control contacts that form the control and/or measurement connections 22 on the switch module 6 are connected to a printed circuit board forming the control and/or measurement printed circuit board 24, which can contain a driver and control circuit.

FIGS. 4a, b show two alternative arrangements of the switch modules 6 in the inverter assembly 1 with respect to one of the phase outputs 5a, b, c. The switch modules 6 are in two groups in FIG. 4a, which are adjacent to one another. A first group has four switch modules 6, which are in contact on the input side with a low-side output 9b, and a second group has four switch modules 6 that are in contact on the input side with a high-side output 9a of the intermediate circuit capacitor 4. The switch modules 6 in the first group, or their switches 12, therefore form the low-side switches, and the switch modules 6 in the second group, or their switches 12, form the high-side switches. It should be noted that the outputs 9a, b on the intermediate circuit capacitor 4 can have a very simple arrangement.

FIG. 4b shows a distribution of the switch modules 6 in which they are not arranged in groups, but instead are intermixed. In particular, the switch modules are arranged symmetrically to a central plane 25. Consequently, the intermediate circuit capacitor 4 must have more outputs 9a, b. This has the advantage, however, that there is less compensating current when the system is in operation. Specifically, there are two switch modules 6 with high-side switches between each pair of switch modules 6 with low-side switches.

The use of discrete switch modules 6 has the advantage over the use of discrete half bridges that there can be different arrangements of potential switches. FIGS. 4a, b show two different possible arrangements, the left-hand one of which corresponds to that shown in the preceding figures. This arrangement has the advantage that all of the measurement and control connections for a specific potential are adjacent to one another, and the direct current connection can also be obtained easily. The arrangement in FIG. 4b has the advantage of fewer commutating cells, thus minimizing the amount of compensating current needed in the intermediate circuit.

Different semiconductor materials and types can be used in the inverter assembly 1. By way of example, Si, SiC, or GaN can be used as the semiconductor material. The semiconductor types can be, e.g., IGBTs, MOSFETs, or cascodes. Using different semiconductor types and materials allows for arrangements other than those shown in FIGS. 4a, b.

Instead of four parallel switch modules 6, there can be another number connected in parallel.

Different power conductors, e.g. Si-IGBTs, SiC-MOSFETs, SiC cascodes, GaN?, can be used within one electrical phase.

Numerous different types of semiconductors can be used simultaneously in the inverter structure, e.g. Si-IGBTs, and SiC-MOSFETs.

The printed circuit board can have control board functions in addition to the driver functions in an interconnect device. The inverter assembly 1 can also contain numerous interconnect devices.

FIGS. 5a, b, c show schematic three dimensional illustrations of a switch module from different perspectives. They show how part of the body 10 is formed by the ceramic/copper printed circuit board 21, the back surface of which is completely covered by the cooling element 18. The input connection 7 and the output connection 8 extend along the X-axis from opposite sides thereof. The input connection 7 and output connection 8 each have a surface that is in the same plane as the ceramic/copper printed circuit board 21 and comes in contact therewith. Part of the exposed ends of the input connection 7 and output connection 8 is bent 90°, forming the input contact surface 14 and output contact surface 16, both of which point downward. The control and/or measurement connection 22 is formed by pins 23 on the upper surface of the switch module 6, which are for the following functions:
drain
gate
kelvin source
source

The switch module 6 has a positioning element 26 with an L-shaped profile on the bottom in this exemplary embodiment. The positioning element 26 can be an integral part of the cooling element 18. The positioning element 26 extends beyond the body 10 of the switch module 6 on either side, along the Y-axis, such that it forms positioning plates 27. These positioning plates 27 have an upright leg in the Y-Z plane and a horizontal leg in the X-Y plane.

There are two cooling connections 19 on the bottom of the switch module 6 that extend downward in the shape of a tube.

FIGS. 6a, b show two switch modules 6 installed in the inverter assembly 1. The switch modules 6 are secured in the inverter assembly by fasteners 28. The fasteners 28 are formed by strips and have L-shaped fastening holes 29 that accommodate the positioning plates 27. The holes 29 have the same shape as the positioning plates 27.

The fasteners 28 have mechanical interfaces 30 with which they are held in place when inserted downward. The mechanical interfaces 30 are formed by holes in this exemplary embodiment, into which screws can be inserted to secure the fasteners 28 in the downward direction. The holes 30 are designed to accommodate downward forces, thus holding the switch modules 6 down and connecting them to the cooling connections 19 and pressing the contact surfaces 14, 16 on the connections 7, 8 against the complementary contact surfaces 15, 17 to obtain or improve the electrical contact.

As can be seen in FIGS. 6a, b, one of the switch modules 6 has a high-side switch and one of the switch modules 6 has a low-side switch. To prevent faulty assembly, the positioning plates 27 and fastening holes 29 are mirror-reversed, such that the switch modules 6 can only be inserted correctly.

An alternative design for the switch module 6 is shown in FIGS. 7a, b. The switch modules in this embodiment are half bridges, and each have two switches 12, specifically a high-side switch and a low-side switch. This switch module 6 also has two ceramic/copper printed circuit boards 21, with the cooling element 18 placed therebetween. There is one switch 12 on each ceramic/copper printed circuit board 21. The positioning element 26 is not shown, but it can be placed thereon. The switch module 6 has two input connections 7 that can be connected to the DC+ and DC− inputs on the intermediate circuit capacitor 4. The switch module 6 only has one output connection 8 with which it can be connected to one of the phase outputs 5a, b, c. Each ceramic/copper printed circuit board 21 has its own control and/or measurement connection 22, the pins 23 of which extend upward, along the Z axis.

FIGS. 7a, b therefore show an alternative design for a half bridge assembly, composed of just one component. In this case, the semiconductor for the high side is on one side, and the semiconductor for the low side is on the other side. Each side has its own cooling surface where the cooling element is located, through which the coolant flows in parallel. The AC-plate forming the output connection 8 connects the two topological switches in the assembly to an electric half bridge and extends outward therefrom. There can also be additional control and measurement connections 22, as described in reference to the preceding figures. There can also be positioning plates 27 in the half bridge assembly, with which they can be oriented and secured in place.

The switch module 6 takes advantage of the third dimension to minimize the necessary installation space for the power semiconductors in the inverter assembly 1.

The switch module 6 is distinctive in that p1 one or more power semiconductors (dies) forming switches 12 for the switch modules 6 can be placed in the Y-Z plane,
the switch module 6 has power connections for the drain and source on opposite sides along the Y-axis,
the switch module 6 is cooled by the cooling element 18, which has an intake and outlet that extend downward, and
the switch module 6 has control and measurement connections (e.g. drain, gate, kelvin-source, source) that extend upward,
the switch module 6 has fastening points (e.g. positioning plates) for the assembly thereof,
instead of two parallel power semiconductors, another number can be used in parallel,
different power semiconductors, e.g. Si-IGBTs, SiC-MOSFETs, SiC cascodes, GaN? Can be used in the chip assembly,
numerous different types of semiconductors can be used simultaneously in the inverter structure, e.g. Si-IGBTs, and SiC-MOSFETs.

One or more power semiconductors can be used in parallel as switches 12 in the switch modules 6, as in FIGS. 5a, b, if a second switch 12 is used instead of the diode 13, such that two SiC-MOSFETs are used, for example, as switches 12. Numerous power semiconductor elements can be also be used in a topological switch, e.g. Si-IGBT+diode (shown by way of example in FIG. 5a), or SiC-cascode. A single control and measurement connection for all of the semiconductors in a switch module 6 extends upward. Each semiconductor could also have individual control and measurement connections.

FIGS. 8a, b, c show different embodiments of the ceramic/copper printed circuit board 21.

The switch 12 and the optional diode 13 are placed on DBC substrate forming a ceramic/copper printed circuit board 21, which connects the drain to the semiconductors, i.e. the switch 12 and the diode 13. The semiconductor elements, i.e. the switch 12 and the diode 13 are placed on copper sections of the ceramic/copper printed circuit board 21, as in the preceding figures.

The ceramic/copper printed circuit board 21, in particular the DBC substrate, can also be used for positioning the control and measurement connections 22. At this point, the copper coating on the ceramic/copper printed circuit board 21 must be divided into numerous parts (FIG. 8a). This can also be part of the lead frame, without touching the DBC substrate (FIG. 8b). The input connection 7 is not connected in FIGS. 5a, b, c with the copper coating of the ceramic/copper printed circuit board 21/DBC substrate. This can be implemented in another assembly, as shown in FIG. 8a, which then requires a connection, e.g. with bond wires, between the input connection and the source contacts on the semiconductor, in particular the switch 12 and/or diode 13. The measurement and control connections 22 that are not connected to their targets by the copper coating in the ceramic/copper printed circuit board 21/DBC substrate, are connected to their targets with connections that are not shown, e.g. bond wires.

The ceramic/copper printed circuit board 21/DBC substrate is connected at the bottom to the cooling element 18 through soldering or sintering, such that heat can be transferred to the coolant, which can be connected to the cooling element with a seal. The cooling element 18 also has a housing over the positioning plates 27 that are needed in order to orient and secure the switch module 6 in a structure, e.g. the inverter structure.

### REFERENCE SYMBOLS

1 inverter assembly
2 DC supply
3 AC supply
4 intermediate circuit capacitor
5a, b, c phase outputs
6 switch module
7 input connection
8 output connection
9a high-side outputs
9b low-side outputs
10 body
11a, b main surfaces of the module
12 switches
13 diodes
14 input contact surfaces
15 complementary input contact surfaces
16 output contact surfaces
17 complementary output contact surface
18 cooling element
19 cooling connection
20 complementary cooling connection
21 ceramic/copper printed circuit board
22 control and/or measurement connection
23 pins
24 control and/or measurement printed circuit board
25 central plane
26 positioning element
27 positioning plate
28 fastener
29 fastening holes
30 mechanical interfaces

1. An inverter assembly for a vehicle, comprising:
a plurality of switch modules, wherein each switch module has at least one switch , wherein some of the switches are high-side switches and some of the switches are low-side switches;
an intermediate circuit capacitor; and
at least one phase output,
wherein the switches are connected to the intermediate circuit capacitor at an input side, and to the at least one phase output at an output side,
wherein the plurality of switch modules each have at least one main surface, wherein the main surfaces are sides of the switch module with a greatest surface area,
wherein the plurality of switch modules are placed in a stack and/or upright in a row, with parallel main surfaces, in the inverter assembly.

2. The inverter assembly according to claim 1, wherein the main sides of the switch modules are parallel to a Y-Z plane, and the intermediate circuit capacitor has at least one main surface and/or surface extension, wherein the main surface of the capacitor is parallel to a X-Y plane.

3. The inverter assembly according to claim 1, wherein each phase output has at least one dedicated high-side switch and at least one dedicated low-side switch.

4. The inverter assembly according to claim 3, wherein each phase output has two or more high-side switches and/or two or more low-side switches, wherein all of the high-side switches for the phase outputs are adjacent to one another, and/or all of the low-side switches for the same phase outputs are adjacent to one another.

5. The inverter assembly according to claim 3, wherein each phase output has two or more high-side switches and/or two or more low-side switches, wherein the high-side switches and low-side switches are arranged symmetrically in relation to a central plane.

6. The inverter assembly according to claim 1, wherein at least one of the switch modules has at least one high-side switch and at least one low-side switch.

7. The inverter assembly according to claim 1, wherein the switch modules have a box-shaped body.

8. The inverter assembly according to claim 1, wherein at least one of the switch modules has at least one power semiconductor functioning as a switch, wherein the power semiconductor is parallel to the main surfaces of the module, and/or extends in a Y-Z plane.

9. The inverter assembly according to claim 1, wherein at least one of the switch modules has a ceramic/copper printed circuit board, wherein the ceramic/copper printed circuit board is parallel to the main surfaces of the module, and/or parallel to a Y-Z plane.

10. The inverter assembly according to claim 1, wherein at least one of the switch modules has a cooling element, wherein the cooling element is parallel to the main surfaces of the module, and/or parallel to a Y-Z plane.

11. The inverter assembly according to claim 10, wherein the cooling element has a cooling connection, wherein the cooling connection extends downward, along a Z-axis.

12. The inverter assembly according to claim 1, wherein at least one of the switch modules has a control and/or measurement connection (22), wherein the control and/or measurement connection extends upward, along a Z-axis.

13. The inverter assembly according to claim 1, wherein at least one of the switch modules has an input connection for the intermediate circuit capacitor, and an output connection for the at least one phase output, wherein the input connection and output connection are on opposite sides of the switch module, and/or extend along an X-axis.

14. The inverter assembly according to claim 13, wherein the input connection has an input contact surface and the output connection has an output contact surface, wherein the contact surfaces are parallel to an X-Y plane, such that contact can be made to the switch module when inserted downward along a Z-axis, and/or a cooling connection can be connected in the downward direction along the Z-axis, such that the switch module can be connected to a cooling circuit when inserted downward, along the Z-axis.

15. A vehicle comprising:
the inverter assembly according to claim 1, for supplying alternating current to a traction motor in the vehicle.
